(19) United States
(12) Patent Application Publication
(10) Pub. No.: US 2016/0029488 A1
(43) Pub. Date: Jan. 28, 2016

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Myung Sam KANG, Suwon-Si (KR); Seung Eun LEE, Suwon-Si (KR); Ki Jung SUNG, Suwon-Si (KR); Yul Kyo CHUNG, Suwon-Si (KR)

(21) Appl. No.: 14/724,496

(22) Filed: May 28, 2015

(30) Foreign Application Priority Data
Jul. 28, 2014 (KR) 10-2014-0095862

(51) Int. Cl. H05K 1/11; H05K 1/05; H05K 3/40; H05K 1/18

(52) U.S. Cl. CPC H05K 1/115; H05K 1/183; H05K 1/056; H05K 3/4038; H05K 2201/09827; H05K 2201/0154; H05K 2201/096

(57) ABSTRACT

There are provided a printed circuit board and a method of manufacturing the same. The printed circuit board according to an exemplary embodiment of the present disclosure includes a metal core; a through via penetrating through the metal core; and an insulating film formed between the metal core and the through via.

### CROSS-REFERENCE TO RELATED APPLICATION

This application claims the benefit of Korean Patent Application No. 10-2014-0095862, filed on Jul. 28, 2014, entitled “Printed Circuit Board and Method of Manufacturing the Same” which is hereby incorporated by reference in its entirety into this application.

### BACKGROUND

The present disclosure relates to a printed circuit board and a method of manufacturing the same.

Recently, a trend toward multi-functionalization and a speed increase of electronic products has been rapidly progressed. In accordance with this trend, an electronic device and a printed circuit board on which the electronic device is mounted have also been developed at a very rapid speed. In the printed circuit board as described above, thinness and lightness, fine circuit implementation, excellent electrical characteristics, high reliability, a high speed signal transfer, and the like, are demanded. In addition, a printed circuit board according to the related art uses a core made of a metal material in order to improve heat dissipating capability of dissipating heat generated from the electronic device mounted thereon.

### RELATED ART DOCUMENT

### Patent Document

(Patent Document 1) Korean Patent No. 0990543

### SUMMARY

An aspect of the present disclosure may provide a printed circuit board having an improved heat dissipating function, and a method of manufacturing the same.

An aspect of the present disclosure may also provide a printed circuit board capable of decreasing costs and time for manufacturing the printed circuit board, and a method of manufacturing the same.

According to an aspect of the present disclosure, a printed circuit board may include: a metal core; a through via penetrating through the metal core; and an insulating film formed between the metal core and the through via.

The metal core may be made of two kinds of metal.

The through via may have a shape in which a diameter thereof is decreased from an upper surface and a lower surface of the metal core to an inner portion thereof.

According to another aspect of the present disclosure, a method of manufacturing a printed circuit board may include: forming a through via hole in a first metal layer; forming an insulating film on an upper portion and a lower portion of the first metal layer and an inner wall of the through via hole; and forming a through via in the through via hole.

The through via hole may be formed in a shape in which a diameter thereof is decreased from an upper surface and a lower surface of the first metal layer to an inner portion thereof.

The method may further include, after the forming of the through via hole, forming a second metal layer on a surface of the first metal layer.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an illustrative diagram showing a printed circuit board according to a first exemplary embodiment of the present disclosure;

FIG. 2 is an illustrative diagram showing a metal core according to an exemplary embodiment of the present disclosure;

FIG. 3 is an illustrative diagram showing a metal core according to another exemplary embodiment of the present disclosure;

FIGS. 4 through 14 are illustrative diagrams showing a method of manufacturing a printed circuit board according to a first exemplary embodiment of the present disclosure;

FIG. 15 is an illustrative diagram showing a printed circuit board according to a second exemplary embodiment of the present disclosure; and

FIGS. 16 through 20 are illustrative diagrams showing a method of manufacturing a printed circuit board according to a second exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

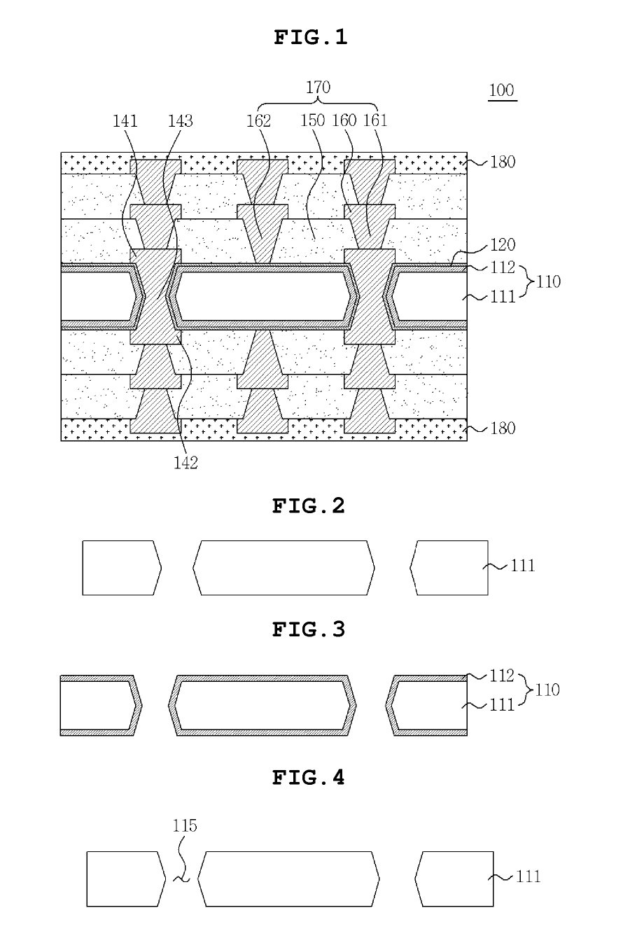

FIG. 1 is an illustrative diagram showing a printed circuit board according to a first exemplary embodiment of the present disclosure.

Referring to FIG. 1, a printed circuit board 100 according to a first exemplary embodiment of the present disclosure includes a metal core 110, a first circuit pattern 141, a second circuit pattern 142, a through via 143, an insulating film 120, and a build-up layer 170.

According to an exemplary embodiment of the present disclosure, the metal core 110 is made of a conductive metal. For example, the metal core 110 is made of copper, nickel, aluminum, silicon carbide (SIC), invar, kovar, or two or more kinds thereof. According to an exemplary embodiment of the present disclosure, the metal core 110 has a double structure including a first metal layer 111 and a second metal layer 112 that are made of materials different from each other. However, the structure of the metal core 110 is not limited thereto. A detailed description of the metal core 110 will be provided below.

In addition, according to an exemplary embodiment of the present disclosure, in the case in which the metal core is made of a metal having low coefficient of thermal expansion (CTE), it is possible to decrease warpage of the printed circuit board 100 at the time of a packaging in which electronic devices (not shown) are mounted on the printed circuit board 100.

According to an exemplary embodiment of the present disclosure, the first circuit pattern 141 is formed on the metal core 110 and the second circuit pattern 142 is formed below the metal core 110. The first circuit pattern 141 and the second circuit pattern 142 according to an exemplary embodiment of the present disclosure are made of a conductive material which is typically used in the field of circuit board. For example, the first circuit pattern 141 and the second circuit pattern 142 are made of copper. In this case, the insulating film 120 is formed on an upper surface and a lower surface of the metal core 110 so as to insulate the metal core 110 from the first circuit pattern 141 and the second circuit pattern 142.

According to an exemplary embodiment of the present disclosure, the through via 143 is formed so as to penetrate through the metal core 110. The through via 143 formed as described above electrically connects the first circuit pattern 141 and the second circuit pattern 142. The through via 143 according to an exemplary embodiment of the present disclosure is formed in a shape in which a diameter thereof is decreased from the upper surface and the lower surface of the metal core 110 to an inner portion thereof. For example, the through via 143 is formed in a sandglass shape.

The through via 143 according to an exemplary embodiment of the present disclosure is made of a conductive material which is typically used in the field of circuit board. For example, the through via 143 is made of copper. In this case, the insulating film 120 is formed between the metal core 110 and the through via 143 so as to electrically insulate the metal core 110 and the through via 143 from each other.

The through via 143 formed as described above also serves to transfer an electrical signal and transfers heat of heating product (not shown) mounted on the printed circuit board 100 to the metal core 110. Since the through via 143 according to an exemplary embodiment of the present disclosure is formed in the metal core 110, it is possible to transfer much heat to the metal core 110. In addition, since the through via 143 is formed in the sandglass shape, it has a wider area which is in contact with the insulating film 120, as compared to a case in which it is formed in a cylindrical shape. That is, since the through via 143 is formed in the sandglass shape, it is possible to transfer the heat to the metal core 110 through the wider area. Therefore, a heat dissipating function is improved by the through via 143 having the sandglass shape according to an exemplary embodiment of the present disclosure.

According to an exemplary embodiment of the present disclosure, the insulating film 120 is entirely formed on at least one surface of the upper surface and the lower surface of the metal core 110. For example, the insulating film 120 is formed on the entire surface of the metal core 110. Therefore, the insulating film 120 is disposed between the first circuit pattern 141, the second circuit pattern 142, the through via 143, the first via 161, and the second via 162, and the metal core 110. The insulating film 120 formed as described above may electrically insulate between the metal core 110 and other components made of the conductive material.

The insulating film 120 according to an exemplary embodiment of the present disclosure may be made of an insulating material which is typically used in the field of circuit board. For example, the insulating film 120 is made of polyimide. However, the polyimide is merely an illustrative material of the insulating film 120, and the material of the insulating film 120 is not limited thereto.

According to an exemplary embodiment of the present disclosure, the build-up layer 170 is formed an upper portion and a lower portion of the metal core 110. The build-up layer 170 according to the preferred embodiment of the present disclosure includes an insulating layer 150, a circuit layer 160, the first via 161, the second via 162, and a protective layer 180.

According to an exemplary embodiment of the present disclosure, the insulating layer 150 is formed the upper portion and the lower portion of the metal core 110. That is, the insulating layer 150 is formed on the insulating film 120 so as to bury the first circuit pattern 141 and the second circuit pattern 142. According to an exemplary embodiment of the present disclosure, the insulating layer 150 may be made of a complex polymer resin which is typically used as an interlayer insulating material. For example, the insulating layer 150 is made of a prepreg, Ajinomoto Build up Film (ABF), and an epoxy based resin such as FR-4, Bismaleimide Triazine (BT), or the like.

According to an exemplary embodiment of the present disclosure, the circuit layer 160 is formed on the insulating layer 150. According to an exemplary embodiment of the present disclosure, the circuit layer 160 is made of a conductive material which is typically used in the field of circuit board. For example, the circuit layer 160 is made of copper.

According to an exemplary embodiment of the present disclosure, the first via 161 and the second via 162 are formed in the insulating layer 150. In addition, according to an exemplary embodiment of the present disclosure, the first via 161 and the second via 162 are made of a conductive material which is typically used in the field of circuit board. For example, the first via 161 and the second via 162 are made of copper. According to an exemplary embodiment of the present disclosure, the first via 161 is formed so as to electrically connect the circuit layer 160 to the first circuit pattern 141 or the second circuit pattern 142. In addition, the second via 162 is formed so that an upper portion thereof is connected to the circuit layer 160 and a lower portion thereof is in contact with the insulating film 120. According to an exemplary embodiment of the present disclosure, the second via 162 which is in contact with the insulating film 120 transfers the heat of the heating product (not shown) mounted on the printed circuit board 100 to the metal core 110.

According to an exemplary embodiment of the present disclosure, the number of insulating layers 150 and circuit layers 160 may be varied depending on a selection of those skilled in the art. In addition, the number of layers and the number of vias that electrically connect the circuit layers 160 on different layers to each other may be varied depending on the selection of those skilled in the art.

According to an exemplary embodiment of the present disclosure, the protective layer 180, which is formed on an outer layer of the build-up layer 170, is formed on the insulating layer 150. The protective layer 180 according to an exemplary embodiment of the present disclosure is formed to prevent the circuit layer 160 from being polluted or oxidized by soldering. For example, the protective layer 180 is made of solder resist.

Since the printed circuit board 100 according to an exemplary embodiment of the present disclosure transfers the heat to the metal core 110 through the through via 143 and the second via 162, heat dissipating performance is improved. Particularly, since the through via 143 is formed in the metal core 110, it is possible to transfer the heat to the metal core 110 through a wider area.

FIG. 2 is an illustrative diagram showing a metal core according to an exemplary embodiment of the present disclosure.

According to an exemplary embodiment of the present disclosure, the metal core is formed of a first metal layer 111. That is, the metal core according to an exemplary embodiment of the present disclosure has a single-layer structure. The first metal layer 111 according to an exemplary embodiment of the present disclosure is made of a conductive metal. For example, the first metal layer 111 is made of copper, nickel, aluminum, silicon carbide (SIC), invar, or kovar. However, a material of the first metal layer 111 is not limited the above-mentioned materials.

FIG. 3 is an illustrative diagram showing a metal core according to another exemplary embodiment of the present disclosure.

According to another exemplary embodiment of the present disclosure, a metal core 110 has a multilayer structure including a first metal layer 111 and a second metal layer 112. Here, the second metal layer 112 is formed on a surface of the first metal layer 111 in order to improve adhesion with an insulating film (not shown) to be formed later. According to an exemplary embodiment of the present disclosure, the first metal layer 111 and the second metal layer 112 are made of a conductive metal. For example, the first metal layer 111 and the second metal layer 112 are made of copper, nickel, aluminum, silicon carbide, invar, or kovar, but are made of materials different from each other.

According to an exemplary embodiment of the present disclosure, the second metal layer 112 is made of copper in order to improve adhesion with the insulating film (not shown) to be formed later. As such, if the second metal layer 112 is made of copper, the first metal layer 111 is made of other conductive metals except for copper.

Although an exemplary embodiment of the present disclosure describes the case in which the second metal layer 112 is made of copper in order to improve adhesion with the insulating film (not shown), by way of example, the present disclosure is not limited thereto. In the case in which the adhesion with the insulating film (not shown) is sufficient, the second metal layer 112 may be made of other conductive materials except for copper.

Although an exemplary embodiment of the present disclosure describes the case in which the metal core 110 is formed in the single-layer structure or the structure of two layers, by way of example, the metal core 110 may be formed in a structure of three layers or more depending on a selection of those skilled in the art.

FIGS. 4 through 14 are illustrative diagrams showing a method of manufacturing a printed circuit board according to a first exemplary embodiment of the present disclosure.

Referring to FIG. 4, a through via hole 115 is formed in the first metal layer 111.

According to an exemplary embodiment of the present disclosure, the first metal layer 111 is made of a conductive metal. For example, the first metal layer 111 is made of copper, nickel, aluminum, silicon carbide (SIC), invar, or kovar. However, a material of the first metal layer 111 is not limited thereto. For example, as long as it is a conductive metal which is typically used in the field of circuit board, any material may be used.

According to an exemplary embodiment of the present disclosure, the through via hole 115 is formed by an exposure and development method. In the case in which the through via hole 115 is formed by the exposure and development method as described above, it is possible to simultaneously form a plurality of through via holes 115. Therefore, the time and costs of forming the through via hole 115 by the exposure and development method may be reduced.

According to an exemplary embodiment of the present disclosure, an etching by the exposure and development may be simultaneously performed on the upper portion and the lower portion of the first metal layer 111. In this case, due to a thick thickness of the first metal layer 111 and an aspect ratio of the first metal layer 111, the through via hole 115 is formed in a shape in which a diameter thereof is decreased from the upper surface and the lower surface of the first metal layer 111 to an inner portion thereof. For example, the through via hole 115 is formed in a sandglass shape.

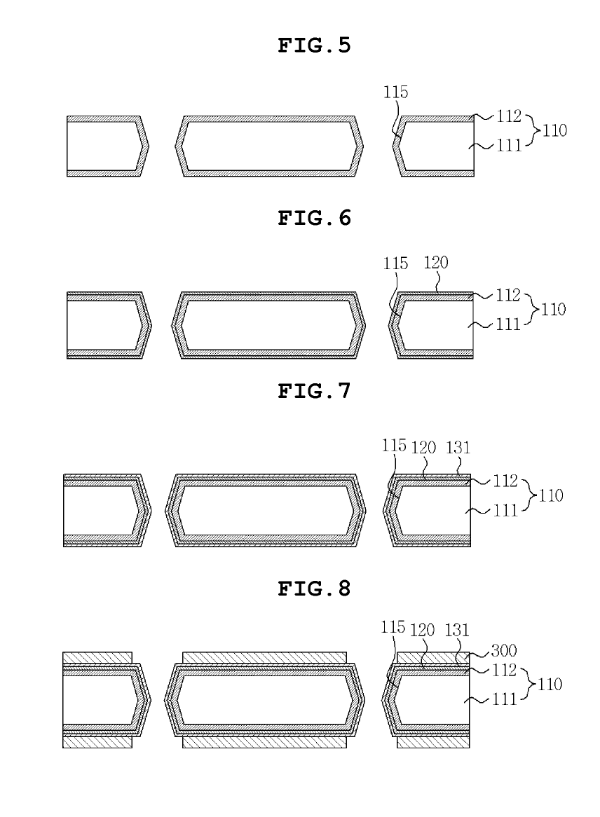

Referring to FIG. 5, a second metal layer 112 is formed.

According to an exemplary embodiment of the present disclosure, the second metal layer 112 is formed on the surface of the first metal layer 111. According to an exemplary embodiment of the present disclosure, the second metal layer 112 is made of a conductive material which is typically used in the field of circuit board. For example, the second metal layer 112 is made of copper, nickel, aluminum, silicon carbide (SIC), invar, or kovar. However, the second metal layer 112 is made of a material different from that of the first metal layer 111.

For example, in the case in which the first metal layer 111 is made of nickel, aluminum, silicon carbide, invar, or kovar, the second metal layer 112 is made of copper in order to improve adhesion with the insulating film (not shown). Therefore, in the case in which the adhesion with the insulating film (not shown) is sufficient, the second metal layer 112 may be made of other metal materials.

According to an exemplary embodiment of the present disclosure, the metal core 110 is formed by forming the second metal layer 112 on the first metal layer 111 in which the through via hole 115 is formed. However, the present disclosure is not limited to the case in which the metal core 110 includes the first metal layer 111 and the second metal layer 112. That is, the metal core 110 may be formed by only the first metal layer 111. In the case in which the metal core 110 is formed by only the first metal layer 111, an operation of forming the second metal layer 112 is omitted.

According to an exemplary embodiment of the present disclosure, the method may further include an operation of forming roughness on the surface of the metal core 110, after the metal core 110 of the single layer structure or the multilayer structure is formed. The operation of forming the roughness as described above allows adhesion between the metal core 110 and the insulating film (not shown) to be formed later to be further improved.

In addition, according to an exemplary embodiment of the present disclosure, in the case in which the metal core 110 is made of a metal having low coefficient of thermal expansion (CTE), it is possible to decrease warpage of the printed circuit board 100 at the time of a packaging in which electronic devices (not shown) are mounted on the printed circuit board 100.

Referring to FIG. 6, an insulating film 120 is formed.

According to an exemplary embodiment of the present disclosure, the insulating film 120 is formed on the surface of the metal core 110. That is, the insulating film 120 is formed on the upper surface and the lower surface of the metal core 110 as well as wall surfaces of the through via hole 115.

For example, if the metal core 110 includes the first metal layer 111 and the second metal layer 112, the insulating film 120 is formed on the surface of the second metal layer 112. Alternatively, if the metal core 110 includes only the first metal layer 111, the insulating film 120 is formed on the surface of the first metal layer 111.

According to an exemplary embodiment of the present disclosure, the insulating film 120 is made of an insulating material which is typically used in the field of circuit board. For example, the insulating film 120 is made of an insulating material which is able to be formed in a thin thickness such as polyimide. However, the polyimide is merely an illustrative material of the insulating film 120, and the material of the insulating film 120 is not limited thereto.

Referring to FIG. 7, a seed layer 131 is formed.

According to an exemplary embodiment of the present disclosure, the seed layer 131 is formed on the surface of the insulating film 120 by a chemical copper plating method or a sputtering method. The seed layer 131 according to an exemplary embodiment of the present disclosure is made of a conductive metal which is typically used in the field of circuit board. For example, the seed layer 131 is made of copper.

Referring to FIG. 8, a plating resist 300 is formed.

According to an exemplary embodiment of the present disclosure, the plating resist 300 is formed on the seed layer 131. In this case, the plating resist 300 is formed so as to have a first circuit pattern (not shown) and a second circuit pattern (not shown) that are to be formed later, and an opening part exposing the seed layer 131 of a region in which the through via (not shown) is formed to the outside.

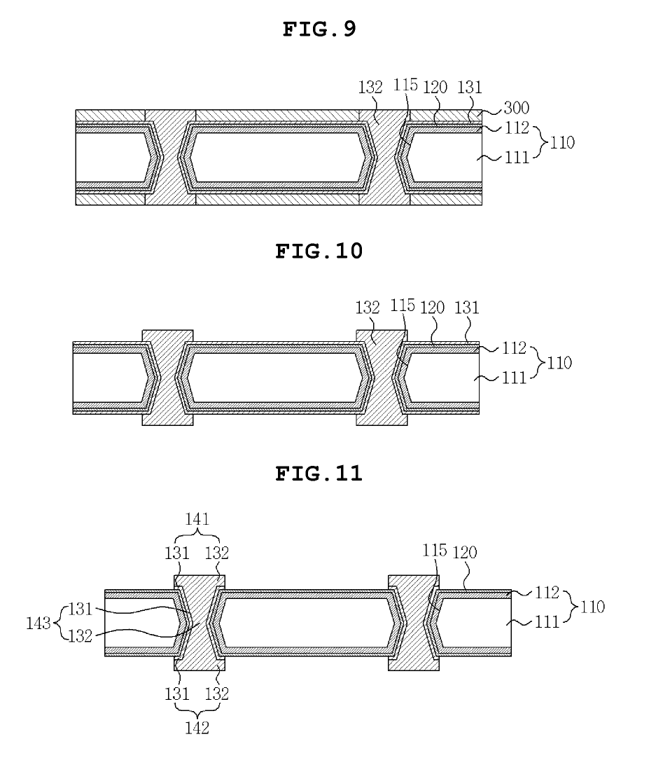

Referring to FIG. 9, a plating operation is performed on the opening part of the plating resist 300.

According to an exemplary embodiment of the present disclosure, a plated layer 132 is formed on the seed layer 131 exposed to the outside by the plating resist 300, by electrolytic plating method. According to an exemplary embodiment of the present disclosure, the plated layer 132 is made of a conductive metal which is typically used in the field of circuit board. For example, the plated layer 132 is made of copper.

Referring to FIG. 10, the plating resist (300 in FIG. 9) is removed.

Referring to FIG. 11, a first circuit pattern 141, a second circuit pattern 142, and a through via 143 are formed.

According to an exemplary embodiment of the present disclosure, the seed layer (131 in FIG. 9) exposed to the outside is removed by removing the plating resist (300 in FIG. 9).

According to an exemplary embodiment of the present disclosure, if the seed layer 131 exposed to the outside is removed, the first circuit pattern 141 including the seed layer 131 and the plated layer 132 is formed on the metal core 110. In addition, the second circuit pattern 142 including the seed layer 131 and the plated layer 132 is formed below the metal core 110. In addition, the through via 143 including the seed layer 131 and the plated layer 132 is formed in the metal core 110. Here, an inner portion of the metal core 110 in which the through via 143 is formed is an inner portion of the through via hole 115.

According to an exemplary embodiment of the present disclosure, since the through via 143 is formed in the metal core 110, it is possible to transfer heat to the metal core 110 through a wide area. That is, a heat dissipating function is improved by the through via 143 according to an exemplary embodiment of the present disclosure.

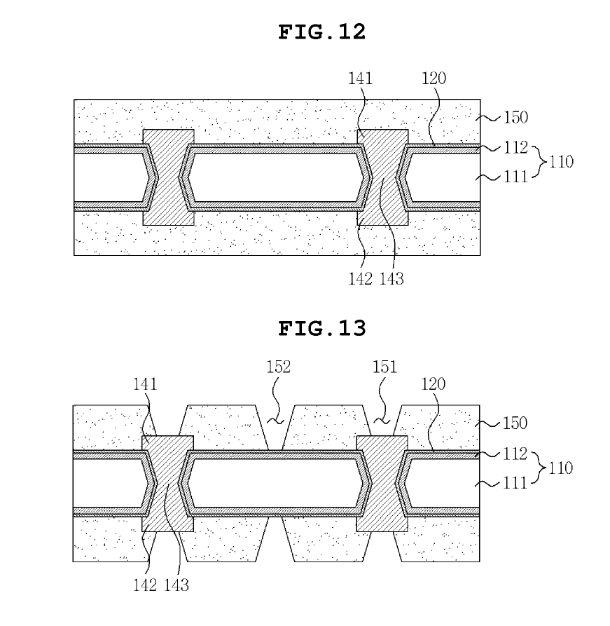

Referring to FIG. 12, an insulating layer 150 is formed.

According to an exemplary embodiment of the present disclosure, the insulating layer 150 is formed on the insulating film 120 so as to bury the first circuit pattern 141 and the second circuit pattern 142.

The insulating layer 150 according to an exemplary embodiment of the present disclosure is formed so as to be stacked on the insulating film 120 in a film form or applied onto the insulating film 120 in a liquid form. The insulating layer 150 according to an exemplary embodiment of the present disclosure is made of a complex polymer resin which is used as an interlayer insulating material. For example, the insulating layer 150 is made of a prepreg, Ajinomoto Build up Film (ABF), and an epoxy based resin such as FR-4, Bismaleimide Triazine (BT), or the like.

FIG. 12 does not show the seed layer (131 in FIG. 11) and the plated layer (132 in FIG. 11) to be classified. However, it is apparent to those skilled in the art from FIG. 12 that the first circuit pattern 141, the second circuit pattern 142, and the through via 143 include the seed layer (131 in FIG. 11) and the plated layer (132 in FIG. 11).

Referring to FIG. 13, a first via hole 151 and a second via hole 152 are formed.

According to an exemplary embodiment of the present disclosure, the first via hole 151 and the second via hole 152 are formed so as to penetrate through the insulating layer 150. According to an exemplary embodiment of the present disclosure, the first via hole 151 is formed so as to expose the upper surface of the first circuit pattern 141 or the second circuit pattern 142. Here, the upper surface of the first circuit pattern 141 and the second circuit pattern 142 is a surface opposite to a surface which is not in contact with the insulating film 120. In addition, the second via hole 152 is formed so as to expose the insulating film 120.

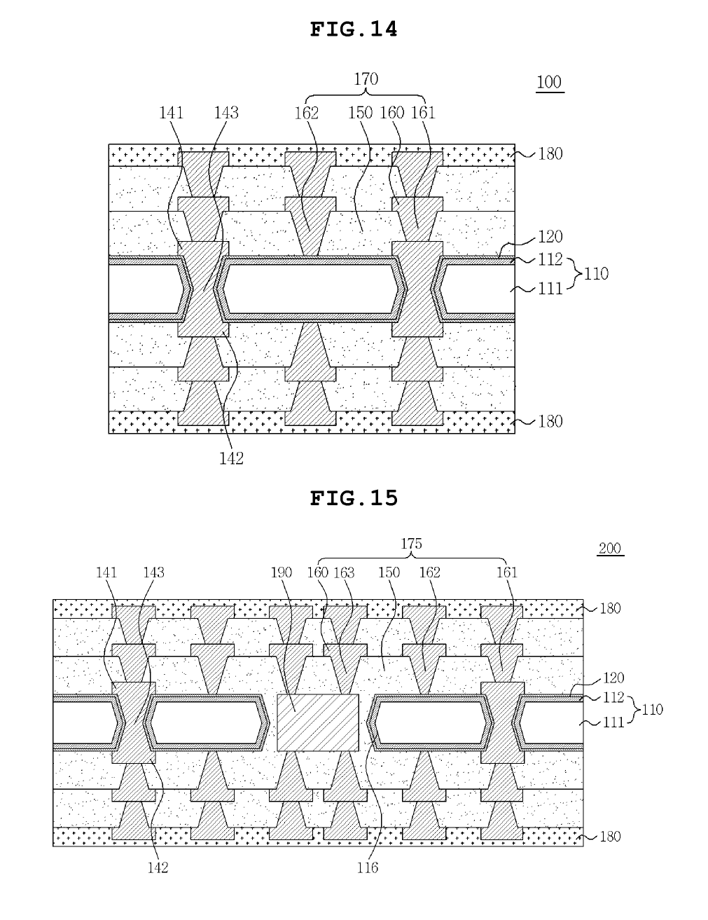

Referring to FIG. 14, a circuit layer 160, a first via 161, and a second via 162 are formed.

According to an exemplary embodiment of the present disclosure, the circuit layer 160 is formed on the insulating layer 150, and the first via 161 and the second via 162 are formed in the first via hole 151 and the second via hole 152, respectively. According to an exemplary embodiment of the present disclosure, the circuit layer 160, the first via 161, and the second via 162 are formed by a method of forming a circuit layer and a via which is known in the field of circuit board. In addition, the circuit layer 160, the first via 161, and the second via 162 are made of a conductive material. For example, the circuit layer 160, the first via 161, and the second via 162 are made of copper.

According to an exemplary embodiment of the present disclosure, the first via 161 is formed so as to electrically connect the circuit layer 160 and the first circuit pattern 141. In addition, the second via 162 is formed so as to have a lower surface which is in contact with the insulating film 120.

According to an exemplary embodiment of the present disclosure, the second via 162 which is in contact with the insulating film 120 may transfer the heat to the metal core 110. Therefore, a heat dissipating function is improved by the second via 162 which is in contact with the insulating film 120.

By the operations shown in FIGS. 12 through 14 as described above, the build-up layer 170 including the insulating layer 150, the circuit layer 160, the first via 161, and the second via 162 is formed. An exemplary embodiment of the present disclosure has described the case in which the build-up layer 170 forms the single layer of the insulating layer 150, the circuit layer 160, the first via 161, and the second via 162. However, it is also possible to form the build-up layer 170 of the multilayer structure as shown in FIG. 14, by repeating the above-mentioned operations depending on the selection of those skilled in the art.

In addition, it is also possible to form the protective layer 180 protecting the circuit layer 160 exposed to the outside of the printed circuit board 100 on the outermost layer of the build-up layer 170. Here, the protective layer 180 is made of solder resist.

FIG. 15 is an illustrative diagram showing a printed circuit board according to a second exemplary embodiment of the present disclosure.

Referring to FIG. 15, a printed circuit board 200 according to a second exemplary embodiment of the present disclosure includes a metal core 110, an electronic device 190, a first circuit pattern 141, a second circuit pattern 142, a through via 143, an insulating film 120, and a build-up layer 175. That is, the printed circuit board 200 according to the second exemplary embodiment of the present disclosure is an embedded substrate in which the electronic device 190 is embedded.

According to an exemplary embodiment of the present disclosure, the metal core 110 is made of a conductive metal. For example, the metal core 110 is made of copper, nickel, aluminum, silicon carbide (SIC), invar, kovar, or two or more kinds thereof. According to an exemplary embodiment of the present disclosure, the metal core 110 has a double structure including a first metal layer 111 and a second metal layer 112 that are made of materials different from each other. However, the structure of the metal core 110 is not limited thereto. A detailed description for the metal core 110 refers to FIGS. 2 and 3.

In addition, according to an exemplary embodiment of the present disclosure, in the case in which the metal core 110 is made of a metal having low coefficient of thermal expansion (CTE), it is possible to decrease warpage caused by the electronic device (not shown) mounted on the printed circuit board at the time of a packaging.

According to an exemplary embodiment of the present disclosure, the metal core 110 has a cavity 116 formed therein. The cavity 116 is a space in which the electronic device 190 is disposed. According to an exemplary embodiment of the present disclosure, the cavity 116 is formed so as to penetrate through the metal core 110. In addition, the cavity 116 is formed in a shape in which a diameter thereof is decreased from an upper surface and a lower surface of the metal core 110 to an inner portion thereof. For example, the cavity 116 is formed in a sandglass shape.

According to an exemplary embodiment of the present disclosure, the electronic device 190 is disposed in the cavity 116. That is, the electronic device 190 is disposed in the metal core 110. For example, the electronic device 190 is a multilayer ceramic capacitor (MLCC). However, a kind of electronic device 190 is not limited to the MLCC, and any kind of electronic device may be used as long as it may be disposed in the printed circuit board.

According to an exemplary embodiment of the present disclosure, the first circuit pattern 141 is formed on the metal core 110 and the second circuit pattern 142 is formed below the metal core 110. The first circuit pattern 141 and the second circuit pattern 142 according to an exemplary embodiment of the present disclosure are made of a conductive material which is typically used in the field of circuit board. For example, the first circuit pattern 141 and the second circuit pattern 142 are made of copper.

According to an exemplary embodiment of the present disclosure, the through via 143 is formed so as to penetrate through the metal core 110. The through via 143 formed as described above electrically connects the first circuit pattern 141 and the second circuit pattern 142. The through vial 143 according to an exemplary embodiment of the present disclosure is formed in a shape in which a diameter thereof is decreased from the upper surface and the lower surface of the metal core 110 to an inner portion thereof. For example, the through via 143 is formed in a sandglass shape. The through via 143 according to an exemplary embodiment of the present disclosure is made of a conductive material which is typically used in the field of circuit board. For example, the through via 143 is made of copper.

The through via 143 formed as described above also serves to transfer an electrical signal and transfers heat of heating product (not shown) mounted on the printed circuit board 200 to the metal core 110. Since the through vial 143 according to an exemplary embodiment of the present disclosure is formed in the sandglass shape in the metal core 110, it is possible to transfer much heat to the metal core 110 through a large area.

According to an exemplary embodiment of the present disclosure, the insulating film 120 is entirely formed on at least one surface of the upper surface and the lower surface of the metal core 110. For example, the insulating film 120 is formed on the entire surface of the metal core 110. Therefore, the insulating film 120 is disposed between the first circuit pattern 141, the second circuit pattern 142, the through via 143, and the first via 161 to the third via 163, and the metal core 110. The insulating film 120 formed as described above may electrically insulate between the metal core 110 and other components made of the conductive material.

The insulating film 120 according to an exemplary embodiment of the present disclosure may be made of an insulating material which is typically used in the field of circuit board. For example, the insulating film 120 is made of polyimide. However, the polyimide is merely an illustrative material of the insulating film 120, and the material of the insulating film 120 is not limited thereto.

According to an exemplary embodiment of the present disclosure, the build-up layer 175 is formed an upper portion and a lower portion of the metal core 110. The build-up layer 175 according to an exemplary embodiment of the present disclosure includes an insulating layer 150, a circuit layer 160, the first via 161 to the third via 163, and a protective layer 180.

According to an exemplary embodiment of the present disclosure, the insulating layer 150 is formed the upper portion and the lower portion of the metal core 110. That is, the insulating layer 150 is formed on the insulating film 120 so as to bury the first circuit pattern 141 and the second circuit pattern 142. In addition, the insulating layer 150 is formed so as to fill the cavity 116 of the metal core 110 in which the electronic device 190 is disposed. According to an exemplary embodiment of the present disclosure, the insulating layer 150 may be made of a complex polymer resin which is typically used as an interlayer insulating material. For example, the insulating layer 150 is made of a prepreg, Ajinomoto Build up Film (ABF), and an epoxy based resin such as FR-4, Bismaleimide Triazine (BT), or the like.

According to an exemplary embodiment of the present disclosure, the circuit layer 160 is formed on the insulating layer 150. According to an exemplary embodiment of the present disclosure, the circuit layer 160 is made of a conductive material which is typically used in the field of circuit board. For example, the circuit layer 160 is made of copper.

According to an exemplary embodiment of the present disclosure, the first via 161 to the third via 163 are formed in the insulating layer 150. In addition, according to an exemplary embodiment of the present disclosure, the first via 161 to the third via 163 are made of a conductive material which is typically used in the field of circuit board. For example, the first via 161 to the third via 163 are made of copper. According to an exemplary embodiment of the present disclosure, the first via 161 is formed so as to electrically connect the circuit layer 160 to the first circuit pattern 141 or the second circuit pattern 142. In addition, the second via 162 is formed so that an upper portion thereof is connected to the circuit layer 160 and a lower potion thereof is connected to the insulating film 120. In addition, the third via 163 is formed so that an upper portion thereof is connected to the circuit layer 160 and a lower potion thereof is connected to an electrode of the electronic device 190. According to an exemplary embodiment of the present disclosure, the second via 162 which is in contact with the insulating film 120 transfers the heat of the heating product (not shown) mounted on the printed circuit board 200 to the metal core 110.

According to an exemplary embodiment of the present disclosure, the number of insulating layers 150 and circuit layers 160 may be varied depending on a selection of those skilled in the art. In addition, the number of layers and the number of vias for a connection between the circuit layers 160 formed on different layers may also be varied depending on the selection of those skilled in the art.

According to an exemplary embodiment of the present disclosure, the protective layer 180, which is formed on an outer layer of the build-up layer 175, is formed on the insulating layer 150. The protective layer 180 according to an exemplary embodiment of the present disclosure is formed to prevent the circuit layer 160 from being polluted or oxidized by soldering. For example, the protective layer 180 is made of solder resist.

Since the printed circuit board 200 according to an exemplary embodiment of the present disclosure transfers the heat to the metal core 110 through the through via 143 and the second via 162, heat dissipating performance is improved. Particularly, since the through vial 143 is formed in the metal core 110, it is possible to transfer the heat to the metal core 110 through a wider area.

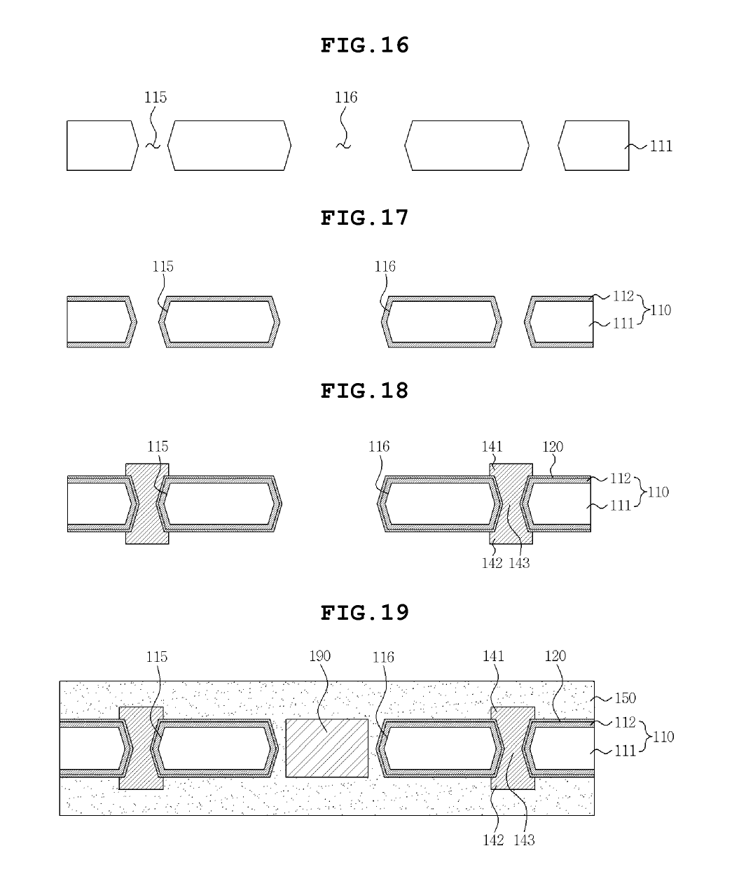

FIGS. 16 through 20 are illustrative diagrams showing a method of manufacturing a printed circuit board 200 according to a second exemplary embodiment of the present disclosure.

Referring to FIG. 16, a through via hole 115 and a cavity 116 are formed in a first metal layer 111.

According to an exemplary embodiment of the present disclosure, the first metal layer 111 is made of a conductive metal. For example, the first metal layer 111 is made of copper, nickel, aluminum, silicon carbide (SIC), invar, or kovar. However, a material of the first metal layer 111 is not limited thereto. For example, as long as it is a conductive metal which is typically used in the field of circuit board, any material may be used.

According to an exemplary embodiment of the present disclosure, the through via hole 115 and the cavity 116 are formed by etching the first metal layer 111 by an exposure and development method. Since a plurality of through via holes 115 may be simultaneously formed in the case in which the exposure and development method as described above is used, the time and costs are reduced.

According to an exemplary embodiment of the present disclosure, in the case in which the upper portion and the lower portion of the first metal layer 111 having a thick thickness are simultaneously etched, the through via hole 115 is formed in a shape in which a diameter thereof is decreased from the upper surface and the lower surface of the first metal layer 111 to an inner portion thereof due to an effect of an aspect ratio of the first metal layer 111. For example, the through via hole 115 and the cavity 116 are formed in a sandglass shape. Here, the electronic device 190 is disposed in the cavity 116 later. Therefore, the cavity 116 is formed so as to have a diameter equal to or larger than a diameter of the electronic device 190 to be mounted later.

Referring to FIG. 17, a second metal layer 112 is formed.

According to an exemplary embodiment of the present disclosure, the second metal layer 112 is formed on the surface of the first metal layer 111, such that the metal core 110 including a first metal layer 111 and a second metal layer 112 is formed.

A detailed description of an operation of forming the second metal layer 112, and the metal core 110 according to an exemplary embodiment of the present disclosure refers to FIG. 5.

Referring to FIG. 18, an insulating film 120, a first circuit pattern 141, a second circuit pattern 142, and a through via 143 are formed.

A detailed description of the operations of forming the insulating film 120, the first circuit pattern 141, the second circuit pattern 142, and the through via 143 according to an exemplary embodiment of the present disclosure refers to FIGS. 6 through 11.

Referring to FIG. 19, the electronic device 190 is disposed in the cavity 116 and the insulating layer 150 is formed.

According to an exemplary embodiment of the present disclosure, the electronic device 190 is disposed in the cavity 116. For example, after a lower portion of the cavity 116 is closed by attaching a supporting film (not shown) to a lower portion of the metal core 110, the electronic device 190 is disposed in the cavity 116. After the electronic device 190 is disposed in the cavity 116, the insulating layer 150 is formed on the upper portion of the metal core 110 and the cavity 116. Thereafter, the supporting film (not shown) is removed and the insulating layer 150 is formed on a lower portion of the metal core 110. In the case in which the electronic device 190 is disposed in the cavity through the above-mentioned processes, the insulating layer 150 is formed.

However, the arrangement of the electronic device 190 and the method of forming the insulating layer 150 described above are merely illustrative examples, and the present disclosure is not limited thereto. That is the arrangement of the electronic device 190 and the method of forming the insulating layer 150 may be varied depending on the selection of those skilled in the art.

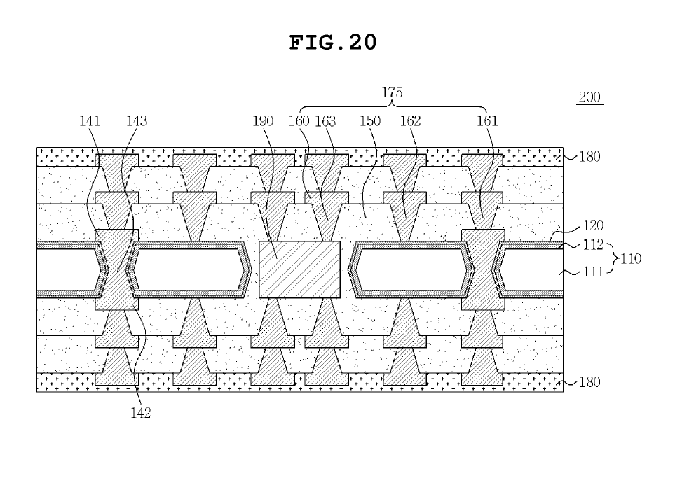

Referring to FIG. 20, a circuit layer 160, and a first via 161 to a third via 163 are formed.

According to an exemplary embodiment of the present disclosure, the circuit layer 160 is formed on the insulating layer 150. In addition, the first via 161 to the third via 163 are formed in the insulating layer 150.

According to an exemplary embodiment of the present disclosure, the first via 161 is formed so as to electrically connect the circuit layer 160 and the first circuit pattern 141. In addition, the second via 162 is formed so as to have a lower surface which is in contact with the insulating film 120. In addition, the third via 163 is formed so that a lower surface thereof is connected to an electrode of the electronic device 190.

A detailed description of the operations of forming the circuit layer 160 and the first via 161 to the third via 163 according to an exemplary embodiment of the present disclosure refers to FIGS. 13 and 14. For reference, the third via 163 according to an exemplary embodiment of the present disclosure is formed by forming a third via hole (not shown) exposing the electrode of the electronic device 190 on the insulating layer 150 and then performing the plating on the third via hole (not shown). In addition, the method of forming the third via 163 in the third via hole (not shown) is not limited to the plating. For example, the third via 163 may be formed by any method of methods of forming the via known in the field of circuit board.

According to an exemplary embodiment of the present disclosure, a multilayer build-up layer 175 as shown in FIG. 20 may also be formed by repeating the operations of forming the circuit layer 160, the first via 161 to the third via 163, and the insulating layer 150 depending on the selection of those skilled in the art. In addition, it is also possible to form the protective layer 180 protecting the circuit layer 160 exposed to the outside of the printed circuit board 100 on the outermost layer of the build-up layer 170. Here, the protective layer 180 is made of solder resist.

As such, the printed circuit board 200 in which the electronic device 190 is embedded according to an exemplary embodiment of the present disclosure is manufactured by the operations shown in FIGS. 16 through 20.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board comprising:
a metal core;
a through via penetrating through the metal core; and
an insulating film formed between the metal core and the through via.

2. The printed circuit board of claim 1, wherein the insulating film is entirely formed on at least one surface of an upper surface and a lower surface of the metal core.

3. The printed circuit board of claim 2, further comprising a via formed on the insulating film so as to be in contact with the insulating film.

4. The printed circuit board of claim 1, wherein the metal core is made of two kinds of metal.

5. The printed circuit board of claim 1, wherein the through via has a shape in which a diameter thereof is decreased from an upper surface and a lower surface of the metal core to an inner portion thereof.

6. A printed circuit board comprising:
a metal core having a cavity formed therein;
an electronic device disposed in the cavity;
a through via penetrating through the metal core; and
an insulating film formed between the metal core and the through via.

7. The printed circuit board of claim 6, wherein the insulating film is entirely formed on at least one surface of an upper surface and a lower surface of the metal core.

8. The printed circuit board of claim 7, further comprising a via formed on the insulating film so as to be in contact with the insulating film.

9. The printed circuit board of claim 6, wherein the metal core is made of two kinds of metal.

10. The printed circuit board of claim 6, wherein the through via has a shape in which a diameter thereof is decreased from an upper surface and a lower surface of the metal core to an inner portion thereof.

11. The printed circuit board of claim 7, wherein the cavity is a through type and has a shape in which a diameter thereof is decreased from an upper surface and a lower surface of the metal core to an inner portion thereof.

12. A method of manufacturing a printed circuit board, the method comprising:
forming a through via hole in a first metal layer;
forming an insulating film on an upper portion and a lower portion of the first metal layer and an inner wall of the through via hole; and
forming a through via in the through via hole.

13. The method of claim 12, wherein in the forming of the through via hole, the through via hole is formed in a shape in which a diameter thereof is decreased from an upper surface and a lower surface of the first metal layer to an inner portion thereof.

14. The method of claim 12, further comprising, after the forming of the through via hole, forming a second metal layer on a surface of the first metal layer.

15. The method of claim 14, wherein the second metal layer is made of a material different from a material of the first metal layer.

16. The method of claim 14, wherein in the forming of the insulating film, the insulating film is formed on a surface of the second metal layer.

17. The method of claim 12, further comprising, after the forming of the through via, forming a via formed on the insulating film and being contact with the insulating film.

18. The method of claim 12, wherein the forming of the through via hole further includes forming a cavity in the first metal layer.

19. The method of claim 18, wherein in the forming of the cavity, the cavity is formed in a shape in which a diameter thereof is decreased from an upper surface and a lower surface of the first metal layer to an inner portion thereof.

20. The method of claim 18, further comprising, after the forming of the cavity, disposing an electronic device in the cavity.
